(19) United States
(12) Patent Application Publication
(10) Pub. No.: US 2010/0059785 A1
(43) Pub. Date: Mar. 11, 2010

(54) LIGHT EMITTING DEVICE AND METHOD OF FABRICATING THE SAME

(75) Inventors: SHEN BO LIN, HSINCHU COUNTY (TW); PIN CHUAN CHEN, HSINCHU COUNTY (TW); CHAO HSIUNG CHANG, HSINCHU COUNTY (TW); CHIEN MIN CHEN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/551,893

(22) Filed: Sep. 1, 2009

(30) Foreign Application Priority Data
Sep. 5, 2008 (TW) 097134020

(51) Int. Cl. H01L 33/00; H01L 21/56

(52) U.S. Cl. 257/99; 438/26; 257/E33.056; 257/E21.502

(57) ABSTRACT

A method of fabricating a light emitting device initially forms a copper clad ceramic board of the light emitting device using hot-pressing technique at high temperature and photolithography process. Next, a circuit of the light emitting device is formed using die bonding and wire bonding/flip-chip processes. Finally, the light emitting device is sealed using transfer molding or injection molding process.

### BACKGROUND OF THE INVENTION

1. Field of the Invention

The present invention relates to a light emitting device and a method of fabricating the light emitting device.

2. Description of the Related Art

As shown in FIG. 1, a traditional method of packaging light emitting devices includes attaching a light emitting diode die 10 to a printed circuit board 20, electrically connecting the light emitting diode die 10 to the printed circuit board 20 using conductive wires 30 and separately connecting a P-type electrode and an N-type electrode of the light emitting diode die 10 to two copper conductive films 40 and 42 on the printed circuit board 20, and finally disposing a transparent encapsulating adhesive 50 to protect the light emitting diode die 10 using molding technique. For example, Japanese Patent Publication No. 2005085989 discloses a multilayer printed circuit board for a light-emitting diode. According to the disclosure of the patent, a light-emitting diode is mounted or connected to the surface of a printed circuit board, and then is sealed with transparent resin. However, the disclosed structure has drawbacks such as impermissible reduction in thickness, poor heat-dissipating efficiency, and low integrated density.

The method of packaging light emitting diode dies on printed circuit boards is one of several popular light emitting diode die packaging methods. The method has advantages of low cost, high production speed, simple manufacturing processes and a thinner package. However, printed circuit boards are made of bismaleimide-triazine epoxy resin, having poor heat-dissipating efficiency and undesirable thicknesses. Moreover, a printed circuit board is fabricated by pressing a plurality of layers of metal sheets, which are then etched to form desired circuits thereon using etching technique, and finally coated with solder mask ink for protection of the circuits. Thus, it has disadvantages as follows:

1. The printed circuit boards are made of bismaleimide-triazine epoxy resin, which has the disadvantages of poor heat-dissipating efficiency; and

2. Substrates made of bismaleimide-triazine epoxy resin suffer from similarly poor heat distribution capability.

### SUMMARY OF THE INVENTION

According to the discussion of Description of the Related Art and to meet the requirements of some interests of related industries, the present invention provides a light emitting device and a method of fabricating the light emitting device for achieving the targets that traditional light emitting devices cannot achieve.

In accordance with one objective, the present invention proposes a light emitting device and a method of fabricating the light emitting device. The method includes thermally bonding a copper foil to a ceramic substrate. Next, predetermined electrode patterns and openings are formed on the copper clad ceramic board using lithography process. Then, a metal layer is formed on the copper clad ceramic board by sequentially electroplating nickel, gold, and silver. Thereafter, a light emitting diode die is disposed on the metal layer using wire-bond or flip-chip bond technique. Finally, the light emitting diode die is encapsulated by epoxy resin, polysiloxane resin, silicone gel, polymethyl methacrylate resin, titanium oxide, silicon oxide or a combination thereof using transfer molding or injection molding process.

To better understand the above-described objectives, characteristics and advantages of the present invention, embodiments, with reference to the drawings, are provided for detailed explanation.

### BRIEF DESCRIPTION OF THE DRAWINGS

The invention will be described according to the appended drawings in which:

FIG. 1 is a cross sectional view showing a traditional light emitting device;

FIG. 2A is a cross sectional view showing a wire-bonded light emitting device according to one embodiment of the present invention;

FIG. 2B is a cross sectional view showing a flip chip bonded light emitting device according to one embodiment of the present invention;

FIG. 3A-3I is a schematic view showing the process steps of fabricating a wire-bonded light emitting device according to one embodiment of the present invention; and

FIG. 4A-4H is a schematic view showing the process steps of fabricating a flip-chip bonded light emitting device according to one embodiment of the present invention.

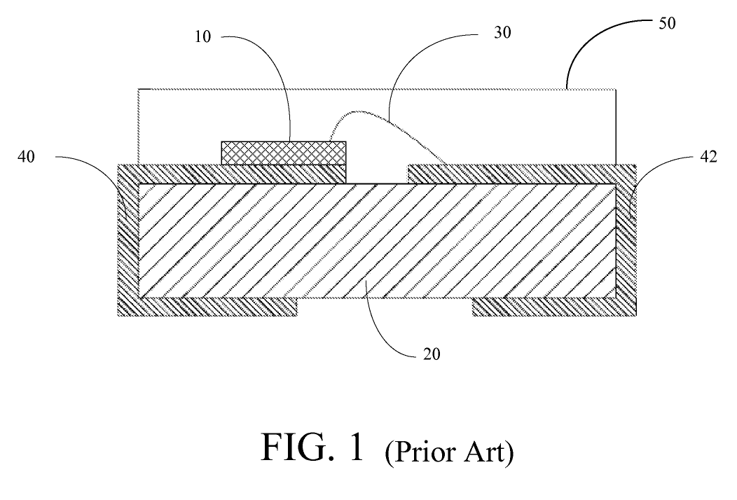

### DETAILED DESCRIPTION OF THE INVENTION

One aspect of the present invention suggests a light emitting device and a method of fabricating the same. In order to thoroughly understand the present invention, detailed descriptions of method steps and components are provided below. Clearly, the implementations of the present invention are not limited to the specific details that are familiar to persons in the art related to a light emitting device and fabrication method thereof. On the other hand, components or method steps, which are well known, are not described in detail. A preferred embodiment of the present invention will be described in detail as follows. However, in addition to the preferred detailed description, other embodiments can be broadly employed, and the scope of the present invention is not limited by any of the embodiments, but should be defined in accordance with the following claims and their equivalent.

The present invention provides a light emitting device and a method of fabricating the same. The light emitting device directly uses a ceramic substrate bonded with copper foils as a base board, on which a suitable circuit pattern is formed so that a light emitting diode die can be disposed on the ceramic board. Therefore, a light emitting device of high integrated density, high heat-dissipating efficiency, and uniform heat-dissipating capability can be obtained.

The ceramic substrate bonded with copper foils, on which a suitable circuit pattern for disposition of a die is formed using standard semiconductor manufacturing processes, is used in the present invention and has a structure manufactured by a method that bonds copper foils to a high temperature calcined ceramic substrate at high temperature using hot-pressing process to form a copper clad ceramic board, on which through vias are formed using a mechanical or laser drilling technique. Next, the through vias are filled with a conductive paste having metal particles, the material of which can be silver, gold, aluminum, copper, chromium, nickel, or an alloy thereof. The conductive paste filled inside the through vias can electrically connect the electrical circuits separately disposed on the upper and lower surfaces of the ceramic substrate. After the through vias are filled, predetermined metal traces (or openings) are formed on the copper clad ceramic board using lithography process. After the circuit patterns are formed, nickel, gold or silver are sequentially plated onto the copper clad ceramic board by electrolytic plating or chemical electroplating. Accordingly, the manufacturing processes of the ceramic board are finished.

Thereafter, a light emitting diode die is die-bonded or eutectically bonded to the ceramic board, close to one side of a through via. Next, metal wires are used to electrically connect the contact pads of the light emitting diode die to the ceramic board. Consequently, the ceramic board is a conductive support frame and a support substrate for the light emitting diode die. Finally, the package process is completed after the light emitting diode die is encapsulated by epoxy resin, polymethyl methacrylate resin, polysiloxane resin, silicone gel, or a combination thereof using transfer molding or injection molding process. The light emitting diode die is covered by transparent protection resin or protection resin containing scattering agent such as titanium dioxide or silicone dioxide so that the light emitting diode die can be protected from moisture.

In another embodiment, the light emitting diode die can be attached to the ceramic board using flip-chip process. The light emitting diode die is directly flipped over, connecting to solder balls via its contact pads. Through solder ball reflow process, the solder balls are melted and solidified so that the electrical connection is completed. Finally, the LED package process is completed after the light emitting diode die is encapsulated by epoxy resin, polymethyl methacrylate resin, polysiloxane resin, silicone gel, or a combination thereof using transfer molding or injection molding process. The light emitting diode die is covered by transparent protection resin or protection resin containing scattering agent such as titanium dioxide or silicone dioxide so that the light emitting diode die can be protected from moisture. The light emitting device of the embodiment has advantages of shorter current path, better heat-dissipating efficiency, and low wire loop height of the bonded wires.

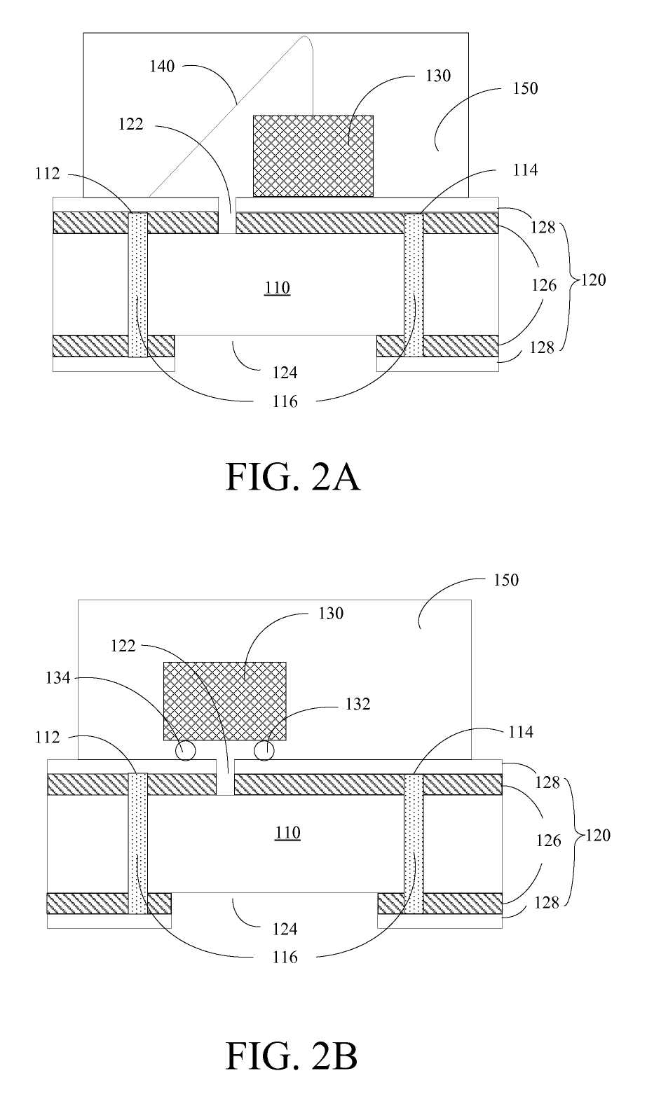

According to the above description, the present invention provides a light emitting device as shown in FIG. 2A. The light emitting device comprises a ceramic substrate 110, a metal structure 120, a light emitting diode die 130, a conductive wire 140, and an encapsulation 150, wherein the ceramic substrate 110 includes two through vias 112 and 114 configured to be filled for electrically connecting the metal layers 128 separately located on the upper and lower sides of the ceramic substrate 110. The metal structure 120 is separately disposed on the upper and lower sides of the ceramic substrate 110, and includes a first opening 122 and a second opening 124, wherein the first opening 122 and the second opening 124 are separately formed on the two sides of the ceramic substrate 110 and a portion of the ceramic substrate 110 between the first opening 122 and the second opening 124 is also between the through vias 112 and 114.

The metal structure 120 comprises a copper foil 126 and a metal layer 128, and the copper foil 126 is between the ceramic substrate 110 and the metal layer 128, wherein the metal layer 128 can be a single layer made of nickel, gold, or silver; or the metal layer 128 can be a multilayer made by sequentially electroplating nickel, gold, and silver onto the copper foil 126. The material of the ceramic substrate 110 can be aluminum oxide or aluminum nitride.

The light emitting diode die 130 is disposed on the metal structure 120. A conductive wire 140 placed over the first opening 122 connects the light emitting diode die 130 to the metal structure 120. The encapsulation 150 covers the light emitting diode 130 at the final stage of the packaging process of the light emitting device.

Referring to FIG. 2B, the light emitting diode die 130 can be directly flipped over, flip-chip bonded to the metal structure 120 via a first metal bump 132 and a second metal bump 134, wherein the first metal bump 132 and the second metal bump 134 can be separately disposed on opposite sides of the first opening 122. The first metal bump 132 and the second metal bump 134 can be solder balls.

Referring to FIGS. 2A and 2B, the through vias 112 and 114 can be filled with conductive paste 116 containing metal particles such that the circuit layers located on the upper and lower sides of the ceramic substrate 110 can be electrically connected. The material of the metal particles can be silver, gold, aluminum, copper, chromium, nickel, and an alloy thereof.

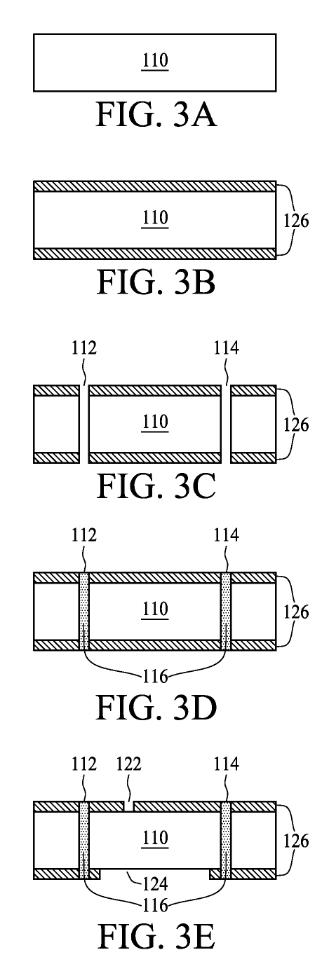

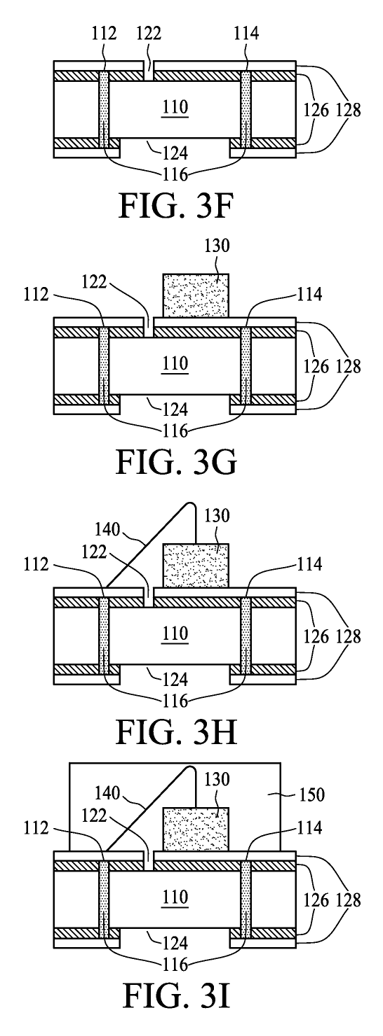

Referring to FIGS. 3A-3I, the invention proposes a fabrication method of a light emitting device. In FIG. 3A, a ceramic substrate 110 is initially provided. In FIG. 3B, copper foils 126 are bonded to the two sides of the ceramic substrate 110.

In FIG. 3C, two through vias 112 and 114, penetrating the ceramic substrate 110 and the copper foils 126, are formed.

In FIG. 3D, the through vias 112 and 114 are separately filled with conductive paste 116 containing metal particles, wherein the material of the metal particle can be silver, gold, aluminum, copper, chromium, nickel, and an alloy thereof.

In FIG. 3E, a first opening 122 and a second opening 124 are formed on the copper foils 126, wherein the first opening 122 and the second opening 124 are on the two sides of the portion of the ceramic substrate 110 between the two through vias 122 and 114.

Thereafter, a metal layer 128 is formed on each copper foil 126, wherein the metal layer 128 can be a single layer made of nickel, gold, or silver; or the metal layer 128 can be a multilayer made by sequentially electroplating nickel, gold, and silver onto the copper foil 126 as shown in FIG. 3F. In FIG. 3G, the light emitting diode die 130 is bonded to the metal layer 128. In FIG. 3H, a conductive wire 140 connects the light emitting diode die 130 to the metal layer 128, wherein the conductive wire 140 connects the light emitting diode die 130 to the metal layer's contact pads located on opposite sides of the first opening 122. In FIG. 3I, the light emitting diode die 130 is finally covered by an encapsulation 150.

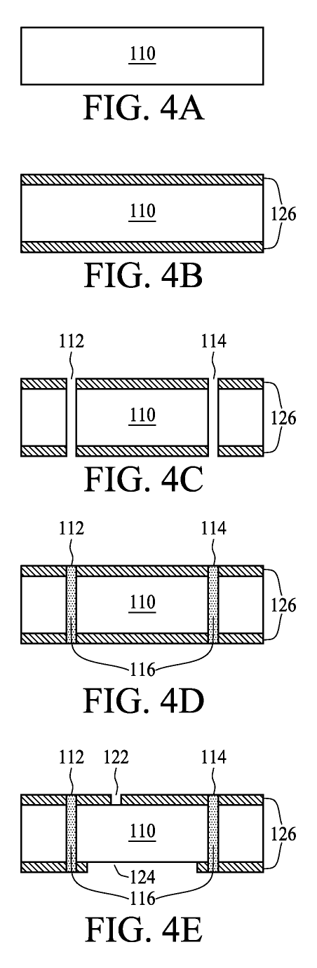

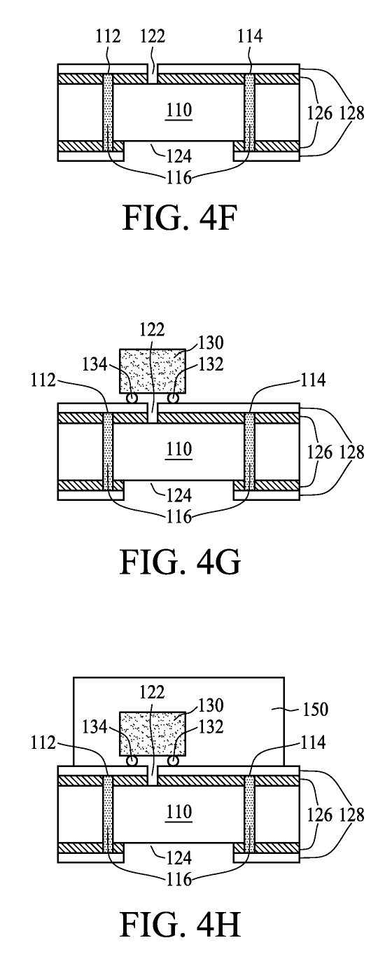

Referring to FIGS. 4A-4H, the light emitting diode die 130 can be directly flipped over, flip-chip bonded to the metal structure 120 via a first metal bump 132 and a second metal bump 134. Referring to FIGS. 4A-4F, the fabrication method initially has the same steps as those shown in FIGS. 3A to 3F. In FIG. 4G, the light emitting diode die 130 can be flip-chip bonded to the metal structure 120 via a first metal bump 132 and a second metal bump 134, wherein the first metal bump 132 and the second metal bump 134 are separately disposed on the two opposite sides of the first opening 122. Finally, the light emitting diode die 130 is covered by an encapsulation 150 as shown in FIG. 4H.

Moreover, the through vias 112 and 114 can be formed on the ceramic substrate 110 and the copper foils 126 using a mechanical or laser drilling technique. The copper foils 126 are bonded to a high temperature calcined ceramic substrate 110 at high temperature using hot-pressing process, and the metal layers 128 can be formed on the copper foils 126 by chemical electro-deposition or electroplating. In addition, the first opening 122 and the second opening 124 can be formed using photolithography process, and the encapsulation 150 can be formed using transfer molding or injection molding process, wherein the material of the encapsulation 150 can be any one or a combination of the following: epoxy resin, polysiloxane resin, silicone gel, polymethyl methacrylate resin, titanium oxide, and silicon oxide.

Clearly, following the description of the above embodiments, the present invention may have many modifications and variations. Therefore, the scope of the present invention shall be considered with the scope of the dependent claims. In addition to the above detailed description, the present invention can be broadly embodied in other embodiments. The above-described embodiments of the present invention are intended to be illustrative only, and should not become a limitation of the scope of the present invention. Numerous alternative embodiments may be devised by persons skilled in the art without departing from the scope of the following claims.

What is claimed is:

1. A light emitting device, comprising:
a copper clad ceramic board formed by bonding two copper foils onto two sides of a ceramic substrate, said ceramic substrate comprising two through vias formed by a via drilling technique and configured to be filled with conductive paste for conducting electrical circuits separately disposed on upper and lower sides of said ceramic substrate, wherein said copper clad ceramic board comprises a first opening and a second opening disposed separately on two sides of said copper clad ceramic board;
a metal layer electroplated on each of said two sides of said copper clad ceramic board;
a light emitting diode die attached to said metal layer;
a conductive wire traveling over said first opening, connecting said light emitting diode die to said metal layer; and
an encapsulation covering said light emitting diode die.

2. The light emitting device of claim 1, wherein the material of said ceramic substrate is aluminum oxide or aluminum nitride.

3. The light emitting device of claim 1, wherein the material of said metal layer includes nickel, gold, silver, and an alloy thereof.

4. The light emitting device of claim 1, further comprising a conductive paste having metal particles, configured to be filled inside said through vias, wherein the material of said metal particle includes silver, gold, aluminum, copper, chromium, nickel, and an alloy thereof.

5. The light emitting device of claim 1, wherein said encapsulation is formed using transfer molding or injection molding process, wherein the material of said encapsulation includes epoxy resin, polysiloxane resin, silicone gel, polymethyl methacrylate resin, titanium oxide, and silicon oxide.

6. The light emitting device of claim 1, wherein said first opening and said second opening are separately located on two sides of a portion of said ceramic substrate between said two through vias.

7. A light emitting device, comprising:
a copper clad ceramic board formed by bonding two copper foils onto two sides of a ceramic substrate, said ceramic substrate comprising two through vias formed by a via drilling technique and configured to be filled with conductive paste for conducting electrical circuits separately disposed on upper and lower sides of said ceramic substrate, wherein said copper clad ceramic board comprises a first opening and a second opening disposed separately on two sides of said copper clad ceramic board;
a metal layer electroplated on each of said two sides of said copper clad ceramic board;
a light emitting diode die connected to said metal layer via a first metal bump and a second metal bump disposed on two opposite sides of said first opening; and
an encapsulation covering said light emitting diode die.

8. The light emitting device of claim 7, wherein the material of said ceramic substrate is aluminum oxide or aluminum nitride.

9. The light emitting device of claim 7, further comprising a conductive paste having metal particles, configured to be filled inside said through vias, wherein the material of said metal particle includes silver, gold, aluminum, copper, chromium, nickel, and an alloy thereof.

10. The light emitting device of claim 7, wherein said metal layer is formed by electrolytic plating or chemical electroplating, wherein the material of said metal layer includes nickel, gold, silver, and an alloy thereof.

11. The light emitting device of claim 7, wherein said encapsulation is formed using transfer molding or injection molding process, wherein the material of said encapsulation includes epoxy resin, polysiloxane resin, silicone gel, polymethyl methacrylate resin, titanium oxide, and silicon oxide.

12. The light emitting device of claim 7, wherein said first opening and said second opening separately located on two sides of a portion of said ceramic substrate between said two through vias.

13. A method of fabricating a light emitting device, comprising steps of:
providing a ceramic substrate;
forming a copper foil on each of the two sides of said ceramic substrate;
forming two through vias penetrating through said copper foils and said ceramic substrate, wherein said two through vias are configured to be filled with conductive paste for conducting electrical circuits separately disposed on said sides of said ceramic substrate;
forming a first opening and a second opening respectively on said copper foils;
forming a metal layer on each of said copper foils;
mechanically and electrically attaching said light emitting diode die to said metal layer; and
forming an encapsulation on said light emitting diode die.

14. The method of claim 13, wherein the step of mechanically and electrically attaching said light emitting diode die comprises a step of connecting said light emitting diode die to said metal layer using a conductive wire, wherein said conductive wire connects said light emitting diode die to said metal layer's contact pads disposed on two opposite sides of said first opening.

15. The method of claim 13, wherein the step of mechanically and electrically attaching said light emitting diode die comprises a step of flip-chip bonding a light emitting diode die to said metal layer via a first metal bump and a second metal bump disposed on two opposite sides of said first opening.

16. The method of claim 13, wherein the material of said ceramic substrate is aluminum oxide or aluminum nitride.

17. The method of claim 13, further comprising a conductive paste having metal particles, configured to be filled inside said through vias, wherein the material of said metal particles includes silver, gold, aluminum, copper, chromium, nickel, and an alloy thereof.

18. The method of claim 13, wherein said metal layer is formed on said copper foil by electrolytic plating or chemical electroplating, wherein the material of said metal layer includes nickel, gold, silver, and an alloy thereof.

19. The method of claim 13, wherein said encapsulation is formed using transfer molding or injection molding process, wherein the material of said encapsulation includes epoxy resin, polysiloxane resin, silicone gel, polymethyl methacrylate resin, titanium oxide, and silicon oxide.

20. The method of claim 13, wherein said first opening and said second opening separately located on two sides of a portion of said ceramic substrate between said two through vias.
